(19) United States
(12) Patent Application Publication
(10) Pub. No.: US 2026/0025145 A1
(43) Pub. Date: Jan. 22, 2026

(54) Analog-to-digital conversion apparatus and method having signal calibration mechanism

(71) Applicant: REALTEK SEMICONDUCTOR CORPORATION, Hsinchu (TW)

(72) Inventors: LIANG-WEI HUANG, Hsinchu (TW); Hsuan-Ting Ho, Hsinchu (TW); Shih-Hsiung Huang, Hsinchu (TW)

(21) Appl. No.: 19/240,932

(22) Filed: Jun. 17, 2025

(30) Foreign Application Priority Data
Jul. 18, 2024 (TW) 113126927

(51) Int. Cl. H03M 1/10; H03M 1/06

(52) U.S. Cl. CPC H03M 1/1023; H03M 1/0626

(57) ABSTRACT

An analog-to-digital conversion apparatus having signal calibration mechanism is provided. Capacitors in an odd and an even conversion circuits in a conversion circuit are switched to perform conversion on a signal feeding to generate odd and even digital signals such that an odd and an even calibration circuit performs mapping thereon according to odd and even capacitance offset tables to generate odd and even calibrated signals. A digital filtering circuit performs digital filtering on the odd and the even calibrated signals according to odd and even filtering parameters and merges the filtered results to generate a merged output digital signal such that a calibration parameter calculation circuit performs filtering thereon to generate an odd and an even inverted error signal and further performs calculation thereon with the corresponding odd and even digital signals to generate odd and even updating parameter to update the odd and the even capacitance offset tables.

### BACKGROUND OF THE INVENTION

### 1. Field of the Invention

The present disclosure relates to an analog-to-digital conversion apparatus and an analog-to-digital conversion method having a signal calibration mechanism.

### 2. Description of Related Art

An analog-to-digital conversion apparatus is an important circuit component to convert a signal from an analog form to a digital form. A common analog-to-digital conversion apparatus may switch capacitors according to a successive-approximation analog-to-digital conversion (SAR ADC) mechanism to perform voltage comparison subsequently to generate digital codes of different bits and output a digital signal accordingly.

However, capacitance offsets in the analog-to-digital conversion apparatus results in an error such that a calibration technology is required therein to calibrate the input signal and the output signal to accomplish the optimal conversion result.

### SUMMARY OF THE INVENTION

In consideration of the problem of the prior art, an object of the present disclosure is to provide analog-to-digital conversion apparatus and an analog-to-digital conversion method having a signal calibration mechanism.

The present invention discloses an analog-to-digital conversion apparatus having a signal calibration mechanism that includes a conversion circuit, a calibration circuit, a digital filtering circuit and a calibration parameter calculation circuit. The conversion circuit includes N odd conversion circuits and N even conversion circuits each having a plurality of capacitors to switch the capacitors according to a successive-approximation analog-to-digital conversion (SAR ADC) mechanism in a time-division manner to perform conversion on a signal feeding operated at a first frequency so as to respectively generate one of N odd digital signals and one of even digital signals operated at a second frequency, wherein the second frequency is 1/(2N) of the first frequency. The calibration circuit includes N odd calibration circuits and N even calibration circuits, wherein the N odd calibration circuits perform mapping on the N odd digital signals according to N odd capacitance offset tables corresponding to the capacitors of the N odd conversion circuits to generate N odd calibration signals, and the Neven calibration circuits perform mapping on the N even digital signals according to N even capacitance offset tables corresponding to the capacitors of the N even conversion circuits to generate N even calibration signals. The digital filtering circuit performs a digital filtering on the N odd calibration signals according to a group of odd filtering parameters and on the Neven calibration signals according to a group of even filtering parameters and merging filter results to generate a merged output digital signal. The calibration parameter calculation circuit performs an inverse filtering on the merged output digital signal respectively according to an inverse of the group of odd filtering parameters and an inverse of the group of even filtering parameters to generate an odd inverted error signal and an even inverted error signal, so as to further perform calculation on the odd inverted error signal and one of the N odd digital signals having a corresponding timing to generate an odd updating parameter to update one of the N odd capacitance offset tables, and perform calculation on the even inverted error signal and one of the Neven digital signals having a corresponding timing to generate an even updating parameter to update one of the N even capacitance offset tables.

The present invention also discloses an analog-to-digital conversion method having a signal calibration mechanism used in an analog-to-digital conversion apparatus that includes steps outlined below. A conversion circuit comprising N odd conversion circuits and N even conversion circuits each having a plurality of capacitors is controlled to switch the capacitors according to a SAR ADC mechanism in a time-division manner to perform conversion on a signal feeding operated at a first frequency so as to respectively generate one of N odd digital signals and one of even digital signals operated at a second frequency, wherein the second frequency is 1/(2N) of the first frequency. Mapping is performed on the N odd digital signals according to N odd capacitance offset tables corresponding to the capacitors of the N odd conversion circuits by N odd calibration circuits comprised by a calibration circuit to generate N odd calibration signals, and mapping is performed on the N even digital signals according to N even capacitance offset tables corresponding to the capacitors of the N even conversion circuits by N even calibration circuits comprised by the calibration circuit to generate N even calibration signals. A digital filtering is performed on the N odd calibration signals according to a group of odd filtering parameters and on the N even calibration signals according to a group of even filtering parameters and filter results are merged to generate a merged output digital signal by a digital filtering circuit. An inverse filtering is performed on the merged output digital signal respectively according to an inverse of the group of odd filtering parameters and an inverse of the group of even filtering parameters by a calibration parameter calculation circuit to generate an odd inverted error signal and an even inverted error signal, so as to further perform calculation on the odd inverted error signal and one of the N odd digital signals having a corresponding timing by the calibration parameter calculation circuit to generate an odd updating parameter to update one of the N odd capacitance offset tables, and perform calculation on the even inverted error signal and one of the N even digital signals having a corresponding timing by the calibration parameter calculation circuit to generate an even updating parameter to update one of the N even capacitance offset tables.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a block diagram of a communication system according to an embodiment of the present invention.

FIG. 2 illustrates a block diagram of the conversion circuit according to an embodiment of the present invention.

FIG. 3 illustrates a block diagram of the odd conversion circuit according to an embodiment of the present invention.

FIG. 4 illustrates a block diagram of the calibration circuit according to an embodiment of the present invention.

FIG. 5 illustrates a block diagram of the digital filtering circuit according to an embodiment of the present invention.

FIG. 6 illustrates a block diagram of the calibration parameter calculation circuit according to an embodiment of the present invention.

FIG. 7 illustrates a diagram of a plurality of unit capacitors according to an embodiment of the present invention.

FIG. 8 illustrates a block diagram of a communication system according to an embodiment of the present invention.

FIG. 9 illustrates a flow chart of an analog-to-digital conversion method having a signal calibration mechanism according to an embodiment of the present invention.

### DETAILED DESCRIPTION OF THE PREFERRED EMBODIMENTS

An aspect of the present invention is to provide an analog-to-digital conversion apparatus and an analog-to-digital conversion method having the signal calibration mechanism to perform a down-sampling on a signal feeding in a time-division manner to generate a plurality of digital signals such that a mapping according capacitance offset tables, a digital filtering and an inversion are performed to generate an error signal to update the capacitance offset tables to converge capacitance offset items. The influence of the offset of the capacitors in conversion circuits of the analog-to-digital conversion apparatus on the conversion can be avoided to accomplish the object of the signal calibration.

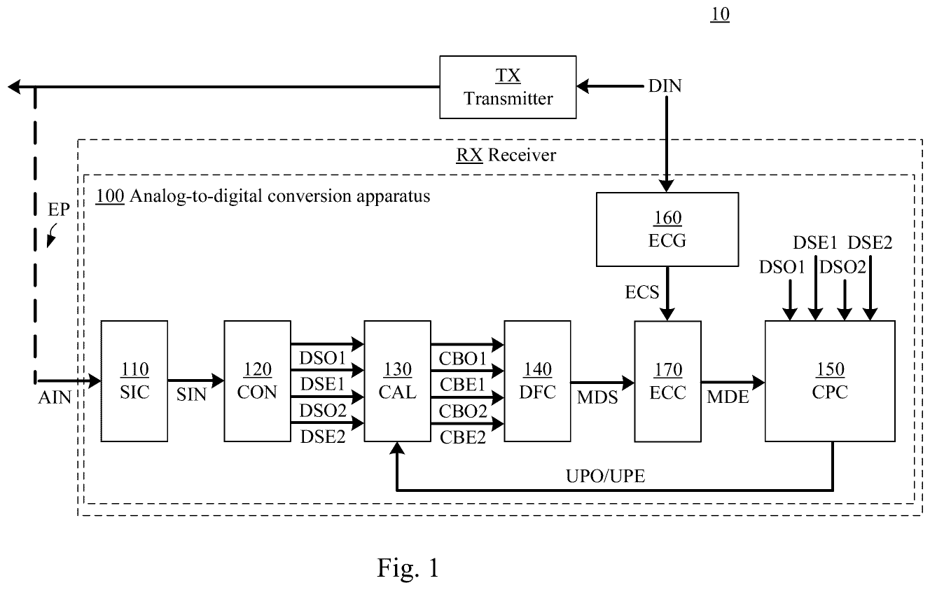

Reference is now made to FIG. 1. FIG. 1 illustrates a block diagram of a communication system 10 according to an embodiment of the present invention. The communication system 10 includes a transmitter TX and a receiver RX.

The transmitter TX may perform a signal transmission. More specifically, the transmitter TX receives a digital signal DIN from a signal source (not illustrated) to perform a digital-to-analog conversion thereon so as to be transmitted to an external circuit. On the contrary, the receiver RX may perform a signal receiving. More specifically, the receiver RX receives an analog signal AIN from an external source to perform analog-to-digital conversion thereon to accomplish the object of the signal receiving.

The receiver RX includes an analog-to-digital conversion apparatus 100 having a signal calibration mechanism. The analog-to-digital conversion apparatus 100 includes a signal input circuit 110 (abbreviated as SIC in FIG. 1), a conversion circuit 120 (abbreviated as CON in FIG. 1), a calibration circuit 130 (abbreviated as CAL in FIG. 1), a digital filtering circuit 140 (abbreviated as DFC in FIG. 1) and a calibration parameter calculation circuit 150 (abbreviated as CPC in FIG. 1).

The signal input circuit 110 processes the analog signal AIN from the external source and having a first frequency to be served as a signal feeding SIN. In an embodiment, the first frequency is such as, but not limited to 800 MHz. The signal input circuit 110 may perform such as, but not limited to filtering, amplifying or a combination thereof on the analog signal AIN to generate the signal feeding SIN also having the first frequency without alternating the frequency.

The conversion circuit 120 includes N odd conversion circuits and N even conversion circuits each having a plurality of capacitors.

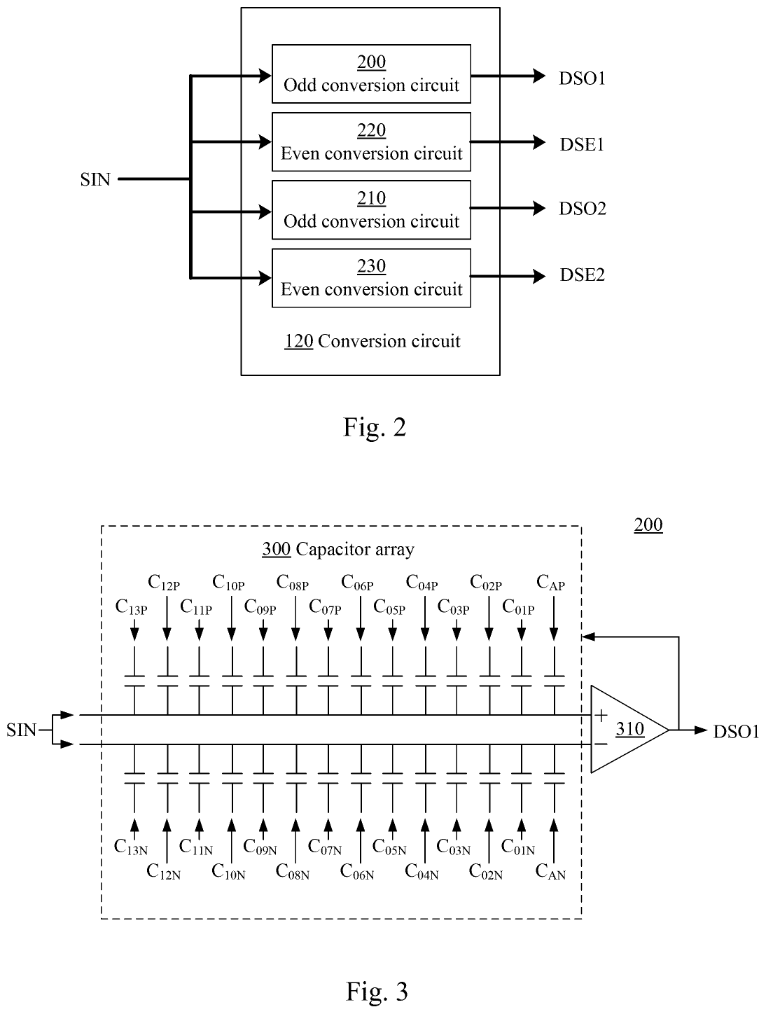

Reference is now made to FIG. 2. FIG. 2 illustrates a block diagram of the conversion circuit 120 according to an embodiment of the present invention. In FIG. 2, the condition that the value of Nis 2 is used as an example to illustrate 2 odd conversion circuits 200 and 210 and 2 even conversion circuits 220 and 230. However, in other embodiments, N can be any positive integer. The present invention is not limited thereto.

Each of the N odd conversion circuits and the N even conversion circuits switches the capacitors therein according to a successive-approximation analog-to-digital conversion (SAR ADC) mechanism in a time-division manner to perform conversion on the signal feeding SIN operated at the first frequency so as to respectively generate one of N odd digital signals and one of even digital signals operated at a second frequency, wherein the second frequency is 1/(2N) of the first frequency.

Take the condition that N is 2 as an example, the odd conversion circuits 200 and 210 generate 2 the odd digital signals DSO1 and DSO2. The even conversion circuits 220 and 230 generate 2 even digital signals DSE1 and DSE2. The odd digital signals DSO1 and DSO2 and the even digital signals DSE1 and DSE2 operate at the second frequency that is ¼ (1/(2×2)) of the first frequency (which is 800 MHZ), equivalent to 200 MHz. In an embodiment, the conversion circuit 120 performs conversion in the time-division manner alternating between the odd circuits and the even circuits, such that the odd conversion circuit 200, the even conversion circuit 220, the odd conversion circuit 210 and the even conversion circuit 230 in turn generate the odd digital signal DSO1, the even digital signal DSE1, the odd digital signal DSO2 and the even digital signal DSE2.

Reference is now made to FIG. 3 at the same time. FIG. 3 illustrates a block diagram of the odd conversion circuit 200 according to an embodiment of the present invention. The odd conversion circuit 200 includes a capacitor array 300 and a comparison circuit 310.

The capacitor array 300 includes capacitors C_{13P}˜C_{01P} and C_{13N}˜C_{01N} arranging from higher bits to lower bits and able to be switched. The capacitor array 300 may selectively include capacitors C_{AP} and C_{AN} corresponding to the lowest bits that are not able to be switched. The analog signal AIN is a differential input signal such that each of the capacitors C_{13P}˜C_{01P} and the capacitors C_{AP} serves as a positive capacitor to receive the positive part of the analog signal AIN from a first terminal thereof, and each of the capacitors C_{13N}˜C_{01N} and the capacitors C_{AN} serves as a negative capacitor to receive the negative part of the analog signal AIN from a first terminal thereof. Since the capacitors C_{13P}˜C_{01P} and C_{AP} and the capacitors C_{13N}˜COIN and C_{AN} are symmetrical structure, the below description is only made to the capacitors C_{13P}˜C_{01P} and C_{AP}. The detail of the capacitors capacitors C_{13N}˜C_{01N} and C_{AN} is not described herein.

In a numerical example, the capacitors C_{13P}˜C_{06P} have capacitances of such as, but not limited to 62C₁, 26C₁, 17C₁, 9C₁, 6C₁, 3C₁, 2C₁ and 1C₁. The capacitors C_{05P}˜C_{01P} have capacitances of such as, but not limited to 7C₂, 4C₂, 2C₂, 1C₂ and 1C₂. The capacitor C_{AP} has a capacitance of such as, but not limited to 1/(2C₂), in which C₁ is a first unit capacitance and C₂ is a second unit capacitance.

In an embodiment, C₁ is 16 and C₂ is 2. As a result, the capacitors C_{13P}˜Co6P have the capacitances of 992, 416, 272, 144, 96, 48, 32 and 16. The capacitors C_{05P}˜C_{01P} have the capacitances of 14, 8, 4, 2 and 2. The capacitor C_{AP} has the capacitance of 1. The capacitors C_{13P}˜C_{01P} and capacitors C_{AP} together have the capacitance of 2047.

The capacitor array 300 may electrically couple a second terminal of each of the capacitors C_{13P}˜C_{01P} to different voltage levels to accomplish the switching mechanism to form different configurations of the capacitors. In an example, each of the capacitors C_{13P}˜C_{06P} can be selectively electrically coupled to a voltage VR or a ground level (not illustrated in the figure). Each of the capacitors C_{05P}˜C_{01P} can be selectively electrically coupled to a voltage 1/(8V_{R}) or the ground level (not illustrated in the figure). Based on the operation described above, the configuration of the capacitors C_{13P}˜C_{01P} serving as the positive capacitors and the capacitors C_{13N}˜COIN serving as the negative capacitors can vary to adjust the voltage values of the positive part and the negative part of the analog signal AIN so as to be compared by the comparison circuit 310 to generate a comparison result.

In an embodiment, from the capacitor C_{13N} and the capacitor C_{13P} corresponding to the highest-bit to the capacitor C_{01N} and the capacitor C_{01P} corresponding to the lowest-bit, the capacitor array 300 varies the capacitor configuration bit-by-bit according to the comparison result generated by the comparison circuit 310 so as to generate an odd digital signal DSO1 according to the comparison results of all the bits.

Equivalently, the behavior of the odd conversion circuit 200 begins with the comparison made by the comparison circuit 310 that compares a difference between the positive part and the negative part of the analog signal AIN with 0 such that a comparison result b13 of the 13-th bit is outputted to be +1 when the comparison result indicates a positive value. After the switching of the capacitor C_{13N} and the capacitor C_{13P} corresponding to the highest bit, the comparison circuit 310 compares the difference between the positive part and the negative part with (V_{R}×b13×62C₁)/2047=(V_{R}×(+1)×992)/2047 such that a comparison result b12 of the 12-th bit is outputted to be −1 when the comparison result indicates a negative value. After the switching of the capacitor C₁₂N and the capacitor C_{12P} corresponding to the second highest bit, the comparison circuit 310 compares the difference between the positive part and the negative part with (V_{R}×(b13×62C₁)×(b12×26C₁))/2047=(V_{R}×((+1)×992)+ ((−1)×416))/2047 such that a comparison result b11 of the 11-th bit is outputted to be −1 when the comparison result indicates a negative value. The operation corresponding to the other bits can be made based on the above description to obtain the comparison results b10˜b00 from the 10-th bit to the 0-th bit. The detail is not described herein.

As a result, the odd digital signal DSO1 can be expressed by the following equation:

$$D S O 1 = dcD + ( b 13 ) \times ( 992 D / 2047 ) + ( b 12 ) \times ( 416 D / 2047 ) + ⋯ ( b 01 ) \times ( 2 D / 2047 ) + ( b 00 ) \times ( 1 D / 2047 ) + Res \qquad ( equation 1 )$$

In (equation1), ‘dcD’ represents a direct current part, and ‘Res’ represents a remained value. ‘D’ in each of the capacitances represents the existence of a capacitance offset value of the capacitance of each of the capacitor deviating from an ideal capacitance due to the influence of the manufacturing process, the voltage or the temperature. For example, the capacitance of the capacitor corresponding to the highest bit may not exactly equal to 992. The capacitance offset value of each of the capacitors may be the same or different depending on the practical condition. Take the highest bit as an example, 992D can be expressed as a sum of the ideal capacitance and the capacitance offset value, which is 992+OFF13, wherein OFF13 is the capacitance offset value of the capacitor C_{13P}. Based on the same rationale, for the capacitors C_{12P}˜Corp and the capacitor C_{AP} corresponding to the other bits, the capacitances thereof can be expressed by the sum of the ideal capacitance and the corresponding capacitance offset values OFF12˜OFF00. The detail is not described herein.

It is appreciated that the configuration described above is merely an example. In other embodiments, the capacitor array 300 may be implemented by other configurations. Further, the operation of each of the odd conversion circuits 210 and the even conversion circuits 220 and 230 may be the same as the operation of the odd conversion circuit 200. The detail is not described herein.

Based on the influence of the capacitance offsets described above, errors exist in the odd digital signal DSO1 and DSO2 and the even digital signals DSE1 and DSE2 outputted by the odd conversion circuits 200 and 210 and the even conversion circuits 220 and 230. The calibration circuit 130 may cooperate with the digital filtering circuit 140 and the calibration parameter calculation circuit 150 to train the parameters related to the degree of the capacitance offsets to eliminate the errors.

The calibration circuit 130 includes N odd calibration circuits and N even calibration circuits. The N odd calibration circuits perform mapping on the N odd digital signals according to N odd capacitance offset tables corresponding to the capacitors of the N odd conversion circuits to generate N odd calibration signals. The N even calibration circuits perform mapping on the N even digital signals according to N even capacitance offset tables corresponding to the capacitors of the N even conversion circuits to generate N even calibration signals.

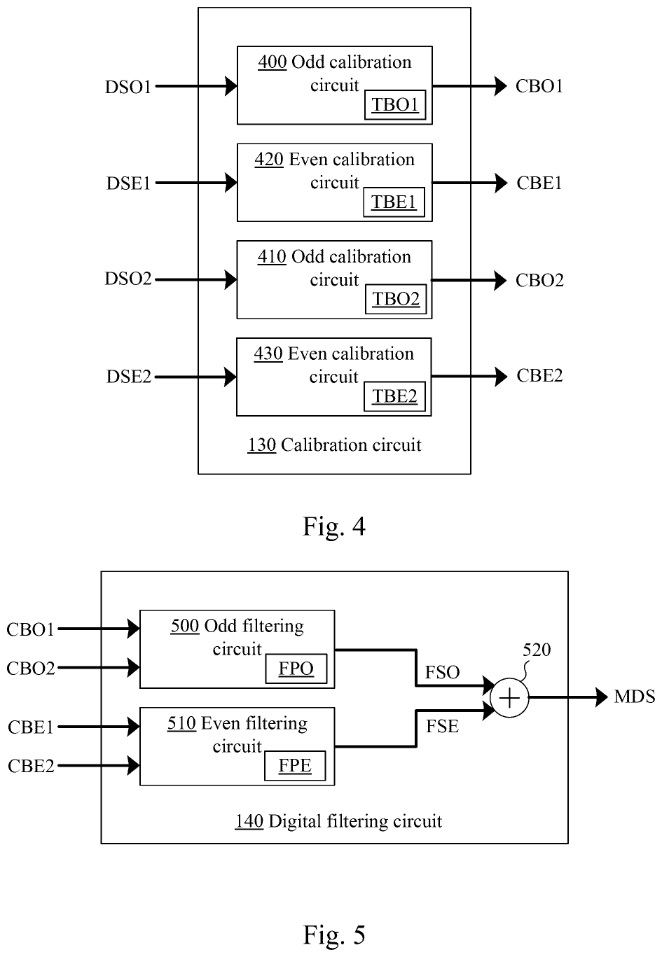

Reference is now made to FIG. 4. FIG. 4 illustrates a block diagram of the calibration circuit 130 according to an embodiment of the present invention.

Take the condition that N is 2 as an example, the calibration circuit 130 includes 2 odd calibration circuits 400 and 410 and 2 even calibration circuits 420 and 430. The odd calibration circuit 400 corresponds to the odd conversion circuit 200 to perform mapping on the odd digital signal DSO1 according to an odd capacitance offset table TBO1 corresponding to the capacitors of the odd conversion circuit 200 to generate an odd calibration signal CBO1. The odd calibration circuit 410 corresponds to the odd conversion circuit 210 to perform mapping on the odd digital signal DSO2 according to an odd capacitance offset table TBO2 corresponding to the capacitors of the odd conversion circuit 210 to generate an odd calibration signal CBO2.

The even calibration circuit 420 corresponds to the even conversion circuit 220 to perform mapping on the even digital signal DSE1 according to an even capacitance offset table TBE1 corresponding to the capacitors of the even conversion circuit 220 to generate an even calibration signal CBE1. The even calibration circuit 430 corresponds to the even conversion circuit 230 to perform mapping on the even digital signal DSE2 according to an even capacitance offset table TBE2 corresponding to the capacitors of the even conversion circuit 230 to generate an even calibration signal CBE2.

Take the odd calibration circuit 400 as an example, the odd capacitance offset table TBO1 may include 14 capacitance offset items corresponding to the capacitors C_{13P}˜C_{01P} and the capacitor C_{AP} in FIG. 2. Take the highest bit as an example, the corresponding capacitance offset item is expressed as a sum of the ideal capacitance and an under-training capacitance offset value, which is 992+TRA13, wherein TRA13 is the under-training capacitance offset value of the capacitor C_{13P}. Based on the same rationale, for the capacitors C_{12P}˜C_{01P} and the capacitor C_{AP} corresponding to the other bits, the capacitance offset items thereof can be expressed by 416+TRA12˜1+TRA00. The detail is not described herein. Each of the odd capacitance offset table TBO2, the even capacitance offset table TBE1 and the even capacitance offset table TBE2 may include a configuration similar to the configuration of the odd capacitance offset table TBO1. The detail is not described herein.

Since the odd calibration circuits 400 and 410 and even calibration circuits 420 and 430 respectively receive the odd digital signals DSO1 and DSO2 and the even digital signals DSE1 and DSE2 to perform mapping, the odd calibration signals CBO1 and CBO2 and the even calibration signals CBE1 and CBE2 are operated at the second frequency.

The digital filtering circuit 140 performs a digital filtering on the N odd calibration signals according to a group of odd filtering parameters and on the N even calibration signals according to a group of even filtering parameters and merges filter results to generate a merged output digital signal.

Reference is now made to FIG. 5. FIG. 5 illustrates a block diagram of the digital filtering circuit 140 according to an embodiment of the present invention.

In an embodiment, the digital filtering circuit 140 includes an odd filtering circuit 500, an even filtering circuit 510 and a merging circuit 520. The odd filtering circuit 500 performs the digital filtering on the odd calibration signals CBO1 and CBO2 according to a group of odd filtering parameters FPO to generate an odd filtered signal FSO. Since the odd filtering circuit 500 receives the odd calibration signals CBO1 and CBO2 to generate the odd filtered signal FSO, the odd filtered signal FSO operates at a frequency that is twice of the second frequency. Take the condition that the second frequency is 200 MHz as an example, the odd filtered signal FSO operates at 400 MHz.

The even filtering circuit 510 performs the digital filtering on the even calibration signals CBE1 and CBE2 according to a group of even filtering parameters FPE to generate an even filtered signal FSE. Based on the rationale same as the odd filtering circuit 500, the even filtered signal FPE also operates at the frequency that is twice of the second frequency.

The merging circuit 520 superimposes the odd filtered signal FSO and the even filtered signal FSE to generate the merged output digital signal MDS.

In an embodiment, since an echo path EP exists between the transmitter TX and the receiver RX, the receiver RX may receive the echo from the transmitter TX when the transmitter TX operates. As a result, as illustrated in FIG. 1, the analog-to-digital conversion apparatus 100 may selectively include an echo canceling signal generation circuit 160 (abbreviated as ECG in FIG. 1) and an echo canceling circuit 170 (abbreviated as ECC in FIG. 1).

The echo canceling signal generation circuit 160 performs a response process according to the digital signal DIN that the transmitter TX is transmitting to generate an echo canceling signal ECS. The echo canceling circuit 170 performs an echo canceling on the merged output digital signal MDS according to the echo canceling signal ECS such that the calibration parameter calculation circuit 150 processes the merged output digital signal MDE having the echo canceling performed thereon. In an embodiment, the response coefficients (not illustrated) that the echo canceling signal generation circuit 160 operates to perform the response process can be updated according to the feedback of the merged output digital signal MDE to accomplish an optimal echo canceling result. The technology of the echo canceling can be referred to U.S. application having the application Ser. No. 18/106,638. The detail is not described herein.

The calibration parameter calculation circuit 150 performs an inverse filtering on the merged output digital signal respectively according to an inverse of the group of odd filtering parameters and an inverse of the group of even filtering parameters to generate an odd inverted error signal and an even inverted error signal, so as to further perform calculation on the odd inverted error signal and one of the N odd digital signals having a corresponding timing to generate an odd updating parameter to update one of the N odd capacitance offset tables, and perform calculation on the even inverted error signal and one of the N even digital signals having a corresponding timing to generate an even updating parameter to update one of the N even capacitance offset tables.

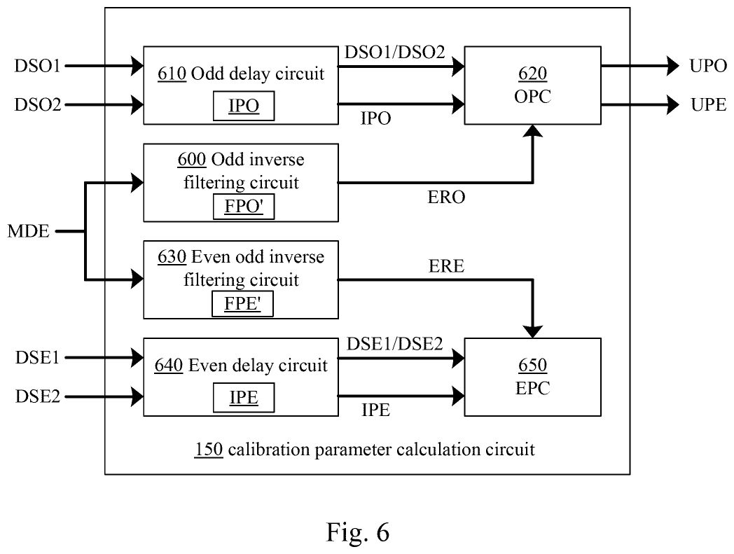

Reference is now made to FIG. 6. FIG. 6 illustrates a block diagram of the calibration parameter calculation circuit 150 according to an embodiment of the present invention. The calibration parameter calculation circuit 150 includes an odd inverse filtering circuit 600, an odd delay circuit 610, an odd parameter calculation circuit 620 (abbreviated as OPC in FIG. 6), an even inverse calculation circuit 630, an even delay circuit 640 and an even parameter calculation circuit 650 (abbreviated as EPC in FIG. 6).

The odd inverse filtering circuit 600 performs inverse filtering on the merged output digital signal MDE according to the inverse of the group of odd filtering parameters FPO′ to generate the odd inverted error signal ERO. The odd inverted error signal ERO that corresponds to the odd part operates at the frequency that is twice of the second frequency, i.e., 400 MHz.

The odd delay circuit 610 delays the odd digital signals DSO1 and DSO2 and records an odd indication signal IPO indicating an order of the odd digital signals DSO1 and DSO2. In an embodiment, the odd delay circuit 610 is implemented by registers to store the content of the odd digital signals DSO1 and DSO2 for a period of time to accomplish the delay function.

The odd parameter calculation circuit 620 retrieves one of the odd digital signals DSO1 and DSO2 having a timing corresponding to the odd inverted error signal ERO from the odd delay circuit 610 to perform calculation to generate the odd updating parameter UPO, and updates one of the odd capacitance offset tables TBO1 and TBO2 and the odd updating parameter UPO.

More specifically, since the odd inverted error signal ERO operates at the frequency that is twice of the second frequency, the odd parameter calculation circuit 620 uses the odd indication signal IPO to determine which one of the odd capacitance offset tables TBO1 and the odd capacitance offset tables TBO2 is updated according to the odd updating parameter UPO generated based on the calculation of the odd inverted error signal ERO.

The even inverse calculation circuit 630 performs inverse filtering on the merged output digital signal MDE according to the inverse of the group of even filtering parameters FPE′ to generate the even inverted error signal ERE. The even inverted error signal ERE that corresponds to the even part operates at the frequency that is twice of the second frequency, i.e., 400 MHz.

The even delay circuit 640 delays the even digital signals DSE1 and DSE2 and records an even indication signal IPE indicating an order of the even digital signals DSE1 and DSE2. In an embodiment, the even delay circuit 640 is implemented by registers to store the content of the even digital signals DSE1 and DSE2 for a period of time to accomplish the delay function.

The even parameter calculation circuit 650 retrieves one of the even digital signals DSE1 and DSE2 having a timing corresponding to the even inverted error signal ERE from the even delay circuit 640 according to the even indication signal IPE to perform calculation to generate the even updating parameter UPE, and updates one of the even capacitance offset tables TBE1 and TBE2 according to the even updating parameter UPE.

More specifically, since the even inverted error signal ERE operates at the frequency that is twice of the second frequency, the even parameter calculation circuit 650 uses the even indication signal IPE to determine which one of the even capacitance offset tables TBE1 and TBE2 is updated according to the even updating parameter UPE generated based on the calculation of the even inverted error signal ERE.

Take the capacitance offset item of the capacitor corresponding to the highest bit that is represented by 992+TRA13 as an example, the updating of the under-training capacitance offset value TRA13 can be expressed by the following equation:

$$T R A 13 = T R A 13 - μ \times U P O \times b 13 \qquad ( equation 2 )$$

In (equation2), ‘μ’ is an adjustable parameter such that the under-training capacitance offset value TRA13 converges faster when the value of μ is larger. ‘b13’ is the comparison result of such a bit. The capacitance offset items of each of the odd capacitance offset table TBO1, the odd capacitance offset table TBO2, the even capacitance offset table TBE1 and the even capacitance offset table TBE2 can be updated by using the method described in (equation2). The detail is not described herein.

When the analog-to-digital conversion apparatus 100 performs the operations described above, specific factors may influence the training result. The following paragraphs in turn describe influences on the training result caused by the dynamic range of the signal feeding SI, the drifting of the gains among different odd conversion circuits and even conversion circuits, the drifting of the offsets among different odd conversion circuits and even conversion circuits and the corresponding coping mechanisms.

When the dynamic range of the signal feeding SIN received by the conversion circuit 120 is not large enough, the capacitors corresponding to the higher-bits are switched in the same way and can not be trained accurately. Under such a condition, the capacitors corresponding to the higher-bits may be configured and switched differently to avoid the inaccurate training result generated due to the insufficient dynamic range.

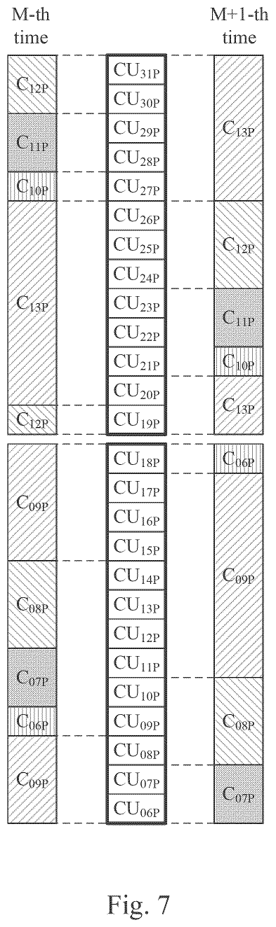

Reference is now made to FIG. 7. FIG. 7 illustrates a diagram of a plurality of unit capacitors CU_{31P}˜CU_{06P} according to an embodiment of the present invention.

In the present embodiment, the higher-bit capacitors C_{13P}˜C_{06P} in the capacitor array 300 in FIG. 3 can be formed by a grouping of the unit capacitors CU_{31P}˜CU_{06P} in FIG. 7. For example, the capacitors C_{13P}˜C_{10P} are respectively formed by the grouping of 7, 3, 2 and 1 of unit capacitors CU_{31P}˜CU_{19P} (totally 13 unit capacitors) each having the capacitance of 140, such that the capacitors C_{13P}˜C₁₀P respectively have the capacitances of 980, 420, 280 and 140. The capacitors C_{06P}˜C_{06P} are respectively formed by the grouping of 7, 3, 2 and 1 of unit capacitors CU_{18P}˜CU_{06P} (totally 13 unit capacitors) each having the capacitance of 15, such that the capacitors CU_{18P}˜CU_{06P} respectively have the capacitances of 85, 45, 30 and 15. On the other hand, each of the capacitors C_{05P}˜C_{01P} and capacitors C_{AP} corresponding to the lower bits in FIG. 3 can be implemented by a single capacitor and is not illustrated in FIG. 7.

Take one of the odd conversion circuits 200 as an example, the odd conversion circuit 200 dynamically adjusts the grouping of the unit capacitors of the higher-bit capacitors each time the capacitors are switched according to the SAR ADC mechanism. In an embodiment, the unit capacitors have a circular arranging order. The odd conversion circuit 200 selects one of the unit capacitors as an initial unit capacitor in a random manner or in turn each time the capacitors are switched according to the SAR ADC mechanism to group the unit capacitors from the initial unit capacitors according to the circular arranging order to form the higher-bit capacitors.

Since the unit capacitance of each of the unit capacitors CU_{31P}˜CU_{19P} and the unit capacitance of each of the unit capacitors CU_{18P}˜CU_{06P} are different, the odd conversion circuit 200 may dynamically adjust the grouping of the unit capacitors CU_{31P}˜CU_{19P} and the grouping of the unit capacitors CU_{18P}˜CU_{06P} respectively.

Take the method of selecting the initial unit capacitor in a random manner as an example, FIG. 7 illustrates the grouping configuration of the odd conversion circuit 200 when the M-th time and the M+1-th time of the performance of the SAR ADC mechanism.

Corresponding to the M-th time of the performance of the SAR ADC mechanism, the odd conversion circuit 200 may randomly select the unit capacitor CU_{26P} as the initial unit capacitor and follow the circular arranging order of the unit capacitors CU_{31P}˜CU_{19P} to group the 7 unit capacitors CU_{26P}˜CU_{20P} to be configured as the capacitor C_{13P} (illustrated as slash blocks in FIG. 7), group the 3 unit capacitors CU_{19P}, CU_{31P}˜CU_{30P} to be configured as the capacitor C_{12P} (illustrated as backslash blocks in FIG. 7), group the 2 unit capacitors CU_{29P}˜CU_{28P} to be configured as the capacitor C₁₁P (illustrated as gray blocks in FIG. 7), and group the unit capacitor CU_{27P} to be configured as the capacitor C_{10P} (illustrated as a block filled with vertical-lines in FIG. 7).

Subsequently, the odd conversion circuit 200 may randomly select the unit capacitor CU_{08P} as the initial unit capacitor and and follow the circular arranging order of the unit capacitors CU_{18P}˜CU_{06P} to group the 7 unit capacitors CU_{08P}˜CU_{06P} and CU_{18P}˜CU_{15P} to be configured as the capacitor C_{06P} (illustrated as slash blocks in FIG. 7), group the 3 unit capacitors CU_{14P}˜CU_{12P} to be configured as the capacitor capacitors C_{08P} (illustrated as backslash blocks in FIG. 7), group the 2 unit capacitors CU_{11P}˜CU_{10P} to be configured as the capacitor Corp (illustrated as gray blocks in FIG. 7) and group the unit capacitor CU_{09P} to be configured as the capacitor C_{06P} (illustrated as a block filled with vertical-lines in FIG. 7).

Corresponding to the M+1-th time of the performance of the SAR ADC mechanism, the odd conversion circuit 200 may select another unit capacitor, e.g., the unit capacitor CU_{20P} to be the initial unit capacitor and follow the circular arranging order of the unit capacitors CU_{31P}˜CU_{19P} to perform grouping thereon to be configured as the capacitors C_{13P}˜C_{10P}. The odd conversion circuit 200 may select another unit capacitor, e.g., the unit capacitor CU_{17P} to be the initial unit capacitor and follow the circular arranging order of the unit capacitors CU_{18P}˜CU_{06P} to perform grouping thereon to be configured as the capacitors C_{06P}˜C_{06P}. The detail is not described herein.

On the other hand, corresponding to the method of selecting the initial unit capacitor in turn, the odd conversion circuit 200 selects two neighboring unit capacitors in turn as the initial unit capacitor to perform grouping in two consecutive times of the performance of the SAR ADC mechanism. For example, the odd conversion circuit 200 may select the unit capacitor CU_{26P} and the unit capacitor CU_{08P} to be the initial unit capacitors to perform the SAR ADC mechanism once, and select the unit capacitor CU_{25P} and the unit capacitor CU_{07P} to be the initial unit capacitors to perform the SAR ADC mechanism once subsequently. So on and so forth.

Besides, in another embodiment, the odd conversion circuit 200 may only select a part of the unit capacitors in the unit capacitors CU_{31P}˜CU_{19P} to dynamically adjusting the grouping thereof, so as to improve the training result with a lower cost under the condition that the dynamic range is not enough.

Each of the odd conversion circuits 210, the even conversion circuits 220 and the even conversion circuits 230 may include a configuration and an operation identical to that of the odd conversion circuits 200. The detail is not described herein. Further, corresponding to the configuration described above, the odd capacitance offset tables TBO1 and TBO2 and the even capacitance offset tables TBE1 and TBE2 may also include the capacitance offset items matching the number of all the unit capacitors included by the higher-bit capacitors and the lower-bit capacitors.

For the numerical example described above, each of the odd capacitance offset tables TBO1 and TBO2 and the even capacitance offset tables TBE1 and TBE2 may include 32 capacitance offset items matching the number of the unit capacitors CU_{31P}˜CU_{06P} and the capacitors C_{05P}˜C_{01P} and the capacitors C_{AP} corresponding to the lower bits, which is 32. The capacitance offset items can therefore be updated and trained to accomplish an optimal training result by using the method of dynamically adjusting the groupings.

When a sampling skew exists among the operation of the odd conversion circuits 200 and 210 and the even conversion circuits 220 and 230 different from each other in the conversion circuit 120, the drifting of the gains occurs among the odd conversion circuits 200 and 210 and the even conversion circuits 220 and 230. Under such a condition, the odd calibration circuits 400 and 410 and the even calibration circuits 420 and 430 may control the gains of the capacitance offset items during the updating of the odd capacitance offset tables TBO1 and TBO2 and the even capacitance offset tables TBE1 and TBE2 to avoid the occurrence of the drifting of the gains.

In an embodiment, the odd calibration circuits 400 and 410 and the even calibration circuits 420 and 430 keep a sum of all the under-training capacitance offset values of the capacitance offset items corresponding to the plurality of higher-bit capacitors of one of the odd capacitance offset tables TBO1 and TBO2 and one of the even capacitance offset tables TBE1 and TBE2 to be 0.

For example, for the odd capacitance offset table TBO1, the odd calibration circuit 400 may subtract each of the under-training capacitance offset values of the unit capacitors CU_{31P}˜CU_{19P} corresponding to the higher-bit capacitors by an average value of the under-training capacitance offset values during the updating of the capacitance offset items to accomplish the object of keeping the sum of all of the under-training capacitance offset values to be 0. By setting such anchor points, the condition that the gains keep increasing such that the converging time increases can be avoided. On the other hand,

The gains of the under-training capacitance offset values in the odd capacitance offset table TBO2 of the odd calibration circuit 410 follow the odd capacitance offset table TBO1 during the updating of capacitance offset items. No anchor point is required to be set.

The even calibration circuits 420 and 430 can use the same method operated in the odd calibration circuits 400 and 410 described above to prevent the gains from keeping increasing. The detail is not described herein.

When the a sampling skew exists among the operation of the odd conversion circuits 200 and 210 and the even conversion circuits 220 and 230 different from each other in the conversion circuit 120, the drifting of the offsets also occurs among the odd conversion circuits 200 and 210 and the even conversion circuits 220 and 230. Under such a condition, the analog-to-digital conversion apparatus may include a direct current amount removing mechanism to avoid the occurrence of the drifting of the offsets.

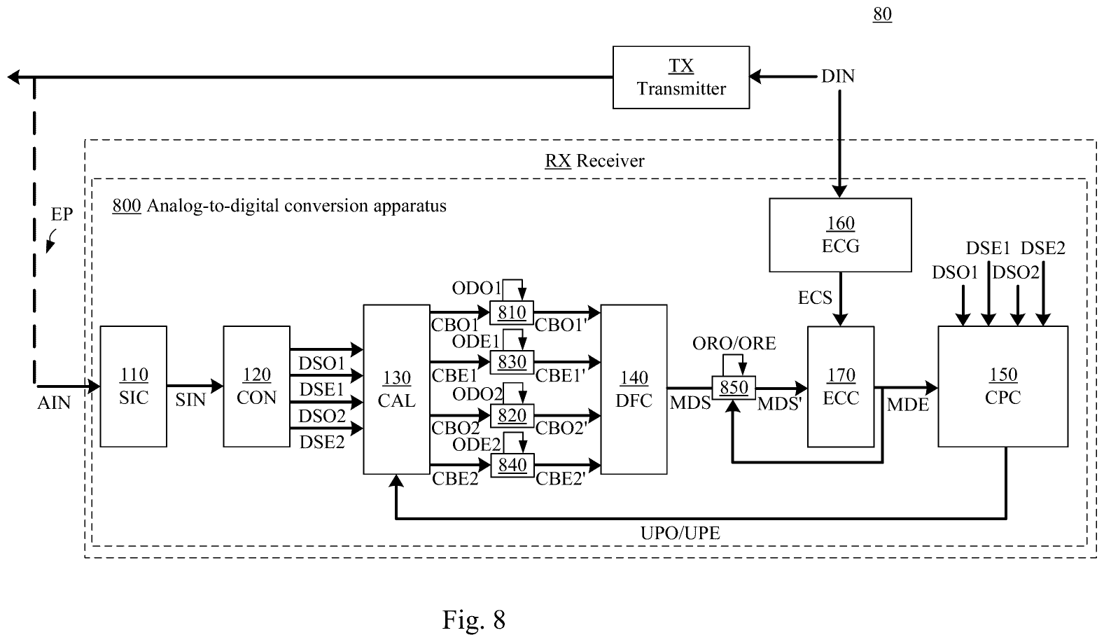

Reference is now made to FIG. 8. FIG. 8 illustrates a block diagram of a communication system 80 according to an embodiment of the present invention. Similar to FIG. 1, the communication system 80 in FIG. 8 includes the transmitter TX and the receiver RX. The receiver RX includes an analog-to-digital conversion apparatus 800 and the analog-to-digital conversion apparatus 800 includes the signal input circuit 110, the conversion circuit 120, the calibration circuit 130, the digital filtering circuit 140 and the calibration parameter calculation circuit 150.

In the present embodiment, the analog-to-digital conversion apparatus 800 further includes N odd front-end direct current amount removing circuits and N even front-end direct current amount removing circuits. The N odd front-end direct current amount removing circuits each converges one of the N odd calibration signals and removes an odd direct current amount thereof such that the digital filtering circuit 140 receives the N odd calibration signals having the odd direct current amount removed. The N even front-end direct current amount removing cirecuits each converges one of the N even calibration signals and removes an even direct current amount thereof such that the digital filtering circuit 140 receives the N even calibration signals having the even direct current amount removed.

Take the condition that N is 2 as an example, the analog-to-digital conversion apparatus 800 includes 2 odd front-end direct current amount removing circuits 810 and 820 and 2 even front-end direct current amount removing circuits 830 and 840. The odd front-end direct current amount removing cirecuits 810 and 820 each converges one of the odd calibration signals CBO1 and CBO2 and removes the odd direct current amounts ODO1 and ODO2 thereof such that the digital filtering circuit 140 receives the odd calibration signals CBO1′ and CBO2′ having the odd direct current amounts ODO1 and ODO2 removed. The even front-end direct current amount removing cirecuits 830 and 840 each converges one of the even calibration signals CBE1 and CBE2 and removes the even direct current amounts ODE1 and ODE2 thereof such that the digital filtering circuit 140 receives the even calibration signals CBE1′ and CBE2′ having the even direct current amount ODE1. ODE2 removed.

The analog-to-digital conversion apparatus 800 further includes a back-end direct current amount removing circuit 850. The back-end direct current amount removing circuit 850 converges and removes an odd remained direct current amount ORO and an even remained direct current amount ORE from the merged output digital signal. In an embodiment, the back-end direct current amount removing circuit 850 converges the odd remained direct current amount ORO and the even remained direct current amount ORE from the merged output digital signal MDE after the echo canceling circuit 170 performs the echo canceling and removes the odd remained direct current amount ORO and the even remained direct current amount ORE from the merged output digital signal MDS before the echo canceling circuit 170 performs the echo canceling such that the echo canceling circuit 170 actually receives the merged output digital signal MDS' having the the odd remained direct current amount ORO and the even remained direct current amount ORE removed.

As a result, the analog-to-digital conversion apparatus having the signal calibration mechanism of the present invention performs a down-sampling on a signal feeding in a time-division manner to generate a plurality of digital signals such that a mapping according capacitance offset tables, a digital filtering and an inversion are performed to generate an error signal to update the capacitance offset tables to converge capacitance offset items. The influence of the offset of the capacitors in conversion circuits of the analog-to-digital conversion apparatus on the conversion can be avoided to accomplish the object of the signal calibration.

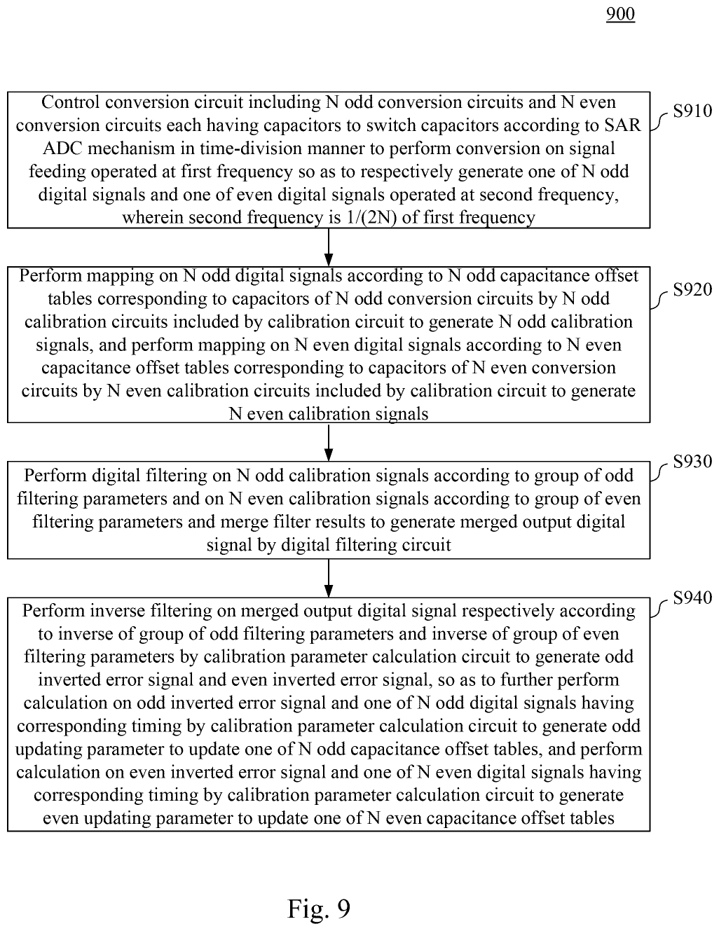

Reference is now made to FIG. 9. FIG. 9 illustrates a flow chart of an analog-to-digital conversion method 900 having a signal calibration mechanism according to an embodiment of the present invention.

Besides the apparatus described above, the present invention further discloses the analog-to-digital conversion method 900 that can be used in such as, but not limited to the analog-to-digital conversion apparatus 100 in FIG. 1. An embodiment of the analog-to-digital conversion method 900 is illustrated in FIG. 9 and includes the steps outlined below.

In step S910, the conversion circuit 120 including N odd conversion circuits and N even conversion circuits (e.g., the odd conversion circuits 200 and 210 and the even conversion circuits 220 and 230) each having the capacitors is controlled to switch the capacitors according to the SAR ADC mechanism in the time-division manner to perform conversion on the signal feeding SIN operated at the first frequency so as to respectively generate one of the N odd digital signals (e.g., the odd digital signals DSO1 and DSO2 in FIG. 2) and one of the even digital signals (e.g., the even digital signals DSE1 and DSE2 in FIG. 2) operated at the second frequency, wherein the second frequency is 1/(2N) of the first frequency.

In step S920, mapping is performed on the N odd digital signals according to the N odd capacitance offset tables (e.g., the odd capacitance offset tables TBO1 and TBO2 in FIG. 4) corresponding to the capacitors of the N odd conversion circuits by the N odd calibration circuits (e.g., the odd calibration circuits 400 and 410 in FIG. 4) included by the calibration circuit 130 to generate N odd calibration signals (e.g., the odd calibration signals CBO1 and CBO2 in FIG. 4), and mapping is performed on the N even digital signals according to the N even capacitance offset tables (e.g., the even capacitance offset tables TBE1 and TBE2 in FIG. 4) corresponding to the capacitors of the N even conversion circuits by the N even calibration circuits (e.g., the even calibration circuits 420 and 430 in FIG. 4) included by the calibration circuit 130 to generate N even calibration signals (e.g., the even calibration signals CBE1 and CBE2 in FIG. 4).

In step S930, the digital filtering is performed on the N odd calibration signals according to the group of odd filtering parameters FPO and on the N even calibration signals according to the group of even filtering parameters FPE and the filter results are merged to generate the merged output digital signal MDS by the digital filtering circuit 140.

In step S940, the inverse filtering is performed on the merged output digital signal MDE respectively according to the inverse of the group of odd filtering parameters FPO′ and the inverse of the group of even filtering parameters FPE′ by the calibration parameter calculation circuit 150 to generate the odd inverted error signal ERO and the even inverted error signal ERE, so as to further perform calculation on the odd inverted error signal ERO and one of the N odd digital signals having the corresponding timing by the calibration parameter calculation circuit 150 to generate the odd updating parameter UPO to update one of the N odd capacitance offset tables, and perform calculation on the even inverted error signal ERE and one of the N even digital signals having the corresponding timing by the calibration parameter calculation circuit 150 to generate the even updating parameter UPE to update one of the N even capacitance offset tables.

It is appreciated that the embodiments described above are merely an example. In other embodiments, it is appreciated that many modifications and changes may be made by those of ordinary skill in the art without departing, from the spirit of the invention.

In summary, the analog-to-digital conversion apparatus and the analog-to-digital conversion method of the present invention perform a down-sampling on a signal feeding in a time-division manner to generate a plurality of digital signals such that a mapping according capacitance offset tables, a digital filtering and an inversion are performed to generate an error signal to update the capacitance offset tables to converge capacitance offset items. The influence of the offset of the capacitors in conversion circuits of the analog-to-digital conversion apparatus on the conversion can be avoided to accomplish the object of the signal calibration.

The aforementioned descriptions represent merely the preferred embodiments of the present disclosure, without any intention to limit the scope of the present disclosure thereto. Various equivalent changes, alterations, or modifications based on the claims of present disclosure are all consequently viewed as being embraced by the scope of the present disclosure.

What is claimed is:

1. An analog-to-digital conversion apparatus having a signal calibration mechanism, comprising:
a conversion circuit comprising N odd conversion circuits and N even conversion circuits each having a plurality of capacitors to switch the capacitors according to a successive-approximation analog-to-digital conversion (SAR ADC) mechanism in a time-division manner to perform conversion on a signal feeding operated at a first frequency so as to respectively generate one of N odd digital signals and one of even digital signals operated at a second frequency, wherein the second frequency is 1/(2N) of the first frequency;
a calibration circuit comprising N odd calibration circuits and N even calibration circuits, wherein the N odd calibration circuits perform mapping on the N odd digital signals according to N odd capacitance offset tables corresponding to the capacitors of the N odd conversion circuits to generate N odd calibration signals, and the N even calibration circuits perform mapping on the N even digital signals according to N even capacitance offset tables corresponding to the capacitors of the N even conversion circuits to generate N even calibration signals;
a digital filtering circuit performing a digital filtering on the N odd calibration signals according to a group of odd filtering parameters and on the N even calibration signals according to a group of even filtering parameters and merging filter results to generate a merged output digital signal; and
a calibration parameter calculation circuit performing an inverse filtering on the merged output digital signal respectively according to an inverse of the group of odd filtering parameters and an inverse of the group of even filtering parameters to generate an odd inverted error signal and an even inverted error signal, so as to further perform calculation on the odd inverted error signal and one of the N odd digital signals having a corresponding timing to generate an odd updating parameter to update one of the N odd capacitance offset tables, and perform calculation on the even inverted error signal and one of the N even digital signals having a corresponding timing to generate an even updating parameter to update one of the N even capacitance offset tables.

2. The analog-to-digital conversion apparatus of claim 1, wherein the calibration parameter calculation circuit comprises:
an odd inverse filtering circuit performing inverse filtering on the merged output digital signal according to the inverse of the group of odd filtering parameters to generate the odd inverted error signal;
an odd delay circuit delaying the N odd digital signals and recording an odd indication signal indicating an order of the N odd digital signals;
an odd parameter calculation circuit retrieving one of the N odd digital signals having a timing corresponding to the odd inverted error signal from the odd delay circuit according to the odd indication signal to perform calculation to generate the odd updating parameter, and updating one of the N odd capacitance offset tables according to the odd updating parameter;
an even inverse calculation circuit performing inverse filtering on the merged output digital signal according to the inverse of the group of even filtering parameters to generate the even inverted error signal;
an even delay circuit delaying the N even digital signals and recording an even indication signal indicating an order of the N even digital signals; and
an even parameter calculation circuit retrieving one of the N even digital signals having a timing corresponding to the even inverted error signal from the even delay circuit according to the even indication signal to perform calculation to generate the even updating parameter, and updating one of the N even capacitance offset tables according to the even updating parameter.

3. The analog-to-digital conversion apparatus of claim 1, wherein the digital filtering circuit comprises:
an odd filtering circuit performing the digital filtering on the N odd calibration signals according to the group of odd filtering parameters to generate an odd filtered signal;
an even filtering circuit performing the digital filtering on the N even calibration signals according to the group of even filtering parameters to generate an even filtered signal; and
a merging circuit superimposing the odd filtered signal and the even filtered signal to generate the merged output digital signal.

4. The analog-to-digital conversion apparatus of claim 1, wherein the analog-to-digital conversion apparatus is used in a receiver (RX) of a communication system, and the analog-to-digital conversion apparatus further comprises:
an echo canceling signal generation circuit performing a response process according to a digital signal that a transmitter (TX) of the communication system is transmitting to generate an echo canceling signal; and
an echo canceling circuit performing an echo canceling on the merged output digital signal according to the echo canceling signal such that the calibration parameter calculation circuit processes the merged output digital signal having the echo canceling performed thereon.

5. The analog-to-digital conversion apparatus of claim 1, wherein a plurality of higher-bit capacitors of the capacitors comprised by each of the N odd conversion circuits and the N even conversion circuits are formed by a grouping of a plurality of unit capacitors each having a same capacitance;
the N odd conversion circuits and the N even conversion circuits dynamically adjust the grouping of the unit capacitors of the higher-bit capacitors each time the capacitors are switched according to the SAR ADC mechanism.

6. The analog-to-digital conversion apparatus of claim 5, wherein the unit capacitors have a circular arranging order, the N odd conversion circuits and the N even conversion circuits select one of the unit capacitors as an initial unit capacitor in a random manner or in turn each time the capacitors are switched according to the SAR ADC mechanism to group the unit capacitors from the initial unit capacitors according to the circular arranging order to form the higher-bit capacitors.

7. The analog-to-digital conversion apparatus of claim 1, wherein the N odd capacitance offset tables and the N even capacitance offset tables each comprises a plurality of capacitance offset items corresponding to the capacitors and each of the capacitance offset items is a sum of an ideal capacitance and an under-training capacitance offset value;
the N odd calibration circuits and the N even calibration circuits keep a sum of all the under-training capacitance offset values of the capacitance offset items corresponding to the plurality of higher-bit capacitors of one of the N odd capacitance offset tables and one of the N even capacitance offset tables to be 0.

8. The analog-to-digital conversion apparatus of claim 1, comprising:
N odd front-end direct current amount removing circuits each converging one of the N odd calibration signals and removing an odd direct current amount thereof such that the digital filtering circuit receives the N odd calibration signals having the odd direct current amount removed; and
N even front-end direct current amount removing circuits each converging one of the N even calibration signals and removing an even direct current amount thereof such that the digital filtering circuit receives the N even calibration signals having the even direct current amount removed.

9. The analog-to-digital conversion apparatus of claim 1, further comprising a back-end direct current amount removing circuit that converges and removes an odd remained direct current amount and an even remained direct current amount from the merged output digital signal.

10. The analog-to-digital conversion apparatus of claim 1, further comprising a signal input circuit to process an analog signal from an external source and having the first frequency to be served as the signal feeding.

11. An analog-to-digital conversion method having a signal calibration mechanism used in an analog-to-digital conversion apparatus, comprising:
controlling a conversion circuit comprising N odd conversion circuits and N even conversion circuits each having a plurality of capacitors to switch the capacitors according to a SAR ADC mechanism in a time-division manner to perform conversion on a signal feeding operated at a first frequency so as to respectively generate one of N odd digital signals and one of even digital signals operated at a second frequency, wherein the second frequency is 1/(2N) of the first frequency;
performing mapping on the N odd digital signals according to N odd capacitance offset tables corresponding to the capacitors of the N odd conversion circuits by N odd calibration circuits comprised by a calibration circuit to generate N odd calibration signals, and performing mapping on the N even digital signals according to N even capacitance offset tables corresponding to the capacitors of the N even conversion circuits by N even calibration circuits comprised by the calibration circuit to generate N even calibration signals;
performing a digital filtering on the N odd calibration signals according to a group of odd filtering parameters and on the N even calibration signals according to a group of even filtering parameters and merging filter results to generate a merged output digital signal by a digital filtering circuit; and
performing an inverse filtering on the merged output digital signal respectively according to an inverse of the group of odd filtering parameters and an inverse of the group of even filtering parameters by a calibration parameter calculation circuit to generate an odd inverted error signal and an even inverted error signal, so as to further perform calculation on the odd inverted error signal and one of the N odd digital signals having a corresponding timing by the calibration parameter calculation circuit to generate an odd updating parameter to update one of the N odd capacitance offset tables, and perform calculation on the even inverted error signal and one of the N even digital signals having a corresponding timing by the calibration parameter calculation circuit to generate an even updating parameter to update one of the N even capacitance offset tables.

12. The analog-to-digital conversion method of claim 11, further comprising:
performing inverse filtering on the merged output digital signal according to the inverse of the group of odd filtering parameters to generate the odd inverted error signal by an odd inverse filtering circuit comprised by the calibration parameter calculation circuit;
delaying the N odd digital signals and recording an odd indication signal indicating an order of the N odd digital signals by an odd delay circuit comprised by the calibration parameter calculation circuit;
retrieving one of the N odd digital signals having a timing corresponding to the odd inverted error signal from the odd delay circuit according to the odd indication signal to perform calculation to generate the odd updating parameter, and updating one of the N odd capacitance offset tables according to the odd updating parameter by an odd parameter calculation circuit comprised by the calibration parameter calculation circuit;
performing inverse filtering on the merged output digital signal according to the inverse of the group of even filtering parameters to generate the even inverted error signal by an even inverse calculation circuit comprised by the calibration parameter calculation circuit;
delaying the N even digital signals and recording an even indication signal indicating an order of the N even digital signals by an even delay circuit comprised by the calibration parameter calculation circuit; and
retrieving one of the N even digital signals having a timing corresponding to the even inverted error signal from the even delay circuit according to the even indication signal to perform calculation to generate the even updating parameter, and updating one of the N even capacitance offset tables according to the even updating parameter by an even parameter calculation circuit comprised by the calibration parameter calculation circuit.

13. The analog-to-digital conversion method of claim 11, further comprising:
performing the digital filtering on the N odd calibration signals according to the group of odd filtering parameters to generate an odd filtered signal by an odd filtering circuit comprised by the digital filtering circuit;
performing the digital filtering on the N even calibration signals according to the group of even filtering parameters to generate an even filtered signal by an even filtering circuit comprised by the digital filtering circuit; and
superimposing the odd filtered signal and the even filtered signal to generate the merged output digital signal by a merging circuit comprised by the digital filtering circuit.

14. The analog-to-digital conversion method of claim 11, wherein the analog-to-digital conversion method is used in a receiver of a communication system, and the analog-to-digital conversion method further comprises:
performing a response process according to a digital signal that a transmitter of the communication system is transmitting to generate an echo canceling signal by an echo canceling signal generation circuit comprised by the analog-to-digital conversion apparatus; and
performing an echo canceling on the merged output digital signal according to the echo canceling signal such that the calibration parameter calculation circuit processes the merged output digital signal having the echo canceling performed thereon by an echo canceling circuit comprised by the analog-to-digital conversion apparatus.

15. The analog-to-digital conversion method of claim 11, wherein a plurality of higher-bit capacitors of the capacitors comprised by each of the N odd conversion circuits and the N even conversion circuits are formed by a grouping of a plurality of unit capacitors each having a same capacitance, the analog-to-digital conversion method further comprising:
dynamically adjusting the grouping of the unit capacitors of the higher-bit capacitors each time the capacitors are switched according to the SAR ADC mechanism by the N odd conversion circuits and the N even conversion circuits.

16. The analog-to-digital conversion method of claim 15, wherein the unit capacitors have a circular arranging order, the analog-to-digital conversion method further comprising:
selecting one of the unit capacitors as an initial unit capacitor in a random manner or in turn each time the capacitors are switched according to the SAR ADC mechanism to group the unit capacitors from the initial unit capacitors according to the circular arranging order to form the higher-bit capacitors by the N odd conversion circuits and the N even conversion circuits.

17. The analog-to-digital conversion method of claim 11, the N odd capacitance offset tables and the N even capacitance offset tables each comprises a plurality of capacitance offset items corresponding to the capacitors and each of the capacitance offset items is a sum of an ideal capacitance and an under-training capacitance offset value, the analog-to-digital conversion method further comprising:
keeping a sum of all the under-training capacitance offset values of the capacitance offset items corresponding to the plurality of higher-bit capacitors of one of the N odd capacitance offset tables and one of the N even capacitance offset tables to be 0 by the N odd calibration circuits and the N even calibration circuits.

18. The analog-to-digital conversion method of claim 11, further comprising:
converging one of the N odd calibration signals and removing an odd direct current amount thereof by each of N odd front-end direct current amount removing circuits such that the digital filtering circuit receives the N odd calibration signals having the odd direct current amount removed; and
converging one of the N even calibration signals and removing an even direct current amount thereof by each of N even front-end direct current amount removing circuits such that the digital filtering circuit receives the N even calibration signals having the even direct current amount removed.

19. The analog-to-digital conversion method of claim 11, further comprising:
converging and removing an odd remained direct current amount and an even remained direct current amount from the merged output digital signal by a back-end direct current amount removing circuit.

20. The analog-to-digital conversion method of claim 11, further comprising:
processing an analog signal from an external source an having the first frequency to be served as the signal feeding by a signal input circuit comprised by the analog-to-digital conversion apparatus.
